(19) United States
(12) Patent Application Publication
(10) Pub. No.: US 2026/0190239 A1
(43) Pub. Date: Jul. 2, 2026

(54) Display Apparatus

(71) Applicant: LG Display Co., Ltd., Seoul (KR)

(72) Inventor: Seung-Won Hwang, Paju-si, Gyeonggi-do (KR)

(21) Appl. No.: 19/429,775

(22) Filed: Dec. 22, 2025

(30) Foreign Application Priority Data
Dec. 30, 2024 (KR) 10-2024-0200247

(51) Int. Cl. H05K 1/189; H05K 7/20; H05K 9/00

(52) U.S. Cl. CPC H05K 1/189; H05K 7/20954; H05K 9/0054; H05K 9/0067; H05K 9/0079

(57) ABSTRACT

The display apparatus according to the present disclosure comprises a plate, a display panel over the plate, a printed circuit board below the plate, a flexible circuit film for connecting electrically the display panel and the printed circuit board, wherein the plate includes an extension portion bent toward a rear surface of the display panel, and wherein the extension portion is bent multiple times in a polygonal shape so that a first side of the extension portion is contacted with the rear surface of the plate and a second side of the extension portion is contacted with the flexible circuit film to support the flexible circuit film.

### CROSS-REFERENCE TO RELATED APPLICATIONS

This application claims priority benefit to Republic of Korea Patent Application No. 10-2024-0200247, filed in the Republic of Korea on December 30, 2024, the entire contents of which is hereby expressly incorporated by reference into the present application.

### Technical Field

The present disclosure relates to a display apparatus, and in particular, for example, without limitation, to the display apparatus capable of enhancing bonding durability of a flexible circuit board and easily discharging static electricity.

### Description of the Related Art

As information technology develops, various types of small and thin display apparatuses such as a liquid crystal display apparatus, an organic light emitting display apparatus, a plasma display apparatus, a micro LED display apparatus, etc. have been proposed.

In this display apparatus, a flexible film is attached to the display panel to apply various signals to the display panel. At this time, since the flexible film, which is a thin film, is bent to be attached to the rear surface of the display panel, there is a problem that a defect occurs in the display apparatus when a crack occurs in the connection area of the flexible film due to an external impact or the like.

### SUMMARY

An object of the present disclosure is to support the flexible circuit film to prevent or reduce separation of the flexible circuit film due to external impact.

Another object of the present disclosure is to provide a display apparatus capable of rapidly discharging heat generated from a driving device to the outside.

In order to achieve the object, the display apparatus according to the present disclosure comprises a plate, a display panel over the plate, a printed circuit board below the plate, a flexible circuit film for connecting electrically the display panel and the printed circuit board, wherein the plate includes an extension portion bent toward a rear surface of the display panel, and wherein the extension portion is bent multiple times in a polygonal shape so that a first side of the extension portion is contacted with the rear surface of the plate and a second side of the extension portion is contacted with the flexible circuit film to support the flexible circuit film.

A driving device is mounted on the flexible printed circuit film and disposed between the flexible circuit film and the extension portion of the plate, and the driving device is contacted with the extension portion of the plate.

The printed circuit board includes a first part formed on an upper surface of the printed circuit board to be connected electrically to the plate and a second part formed on the upper surface of the printed circuit board to be connected electrically to the flexible circuit film.

The first part is a copper foil, and a double-sided conductive tape is disposed between the first part and the plate.

The first part surrounds the second part, and a first pad unit is formed in the second part. a window is formed in the plate corresponding to the second part of the printed circuit board, so that the second part is exposed through the window, and a second pad unit is formed at the end of the flexible circuit board to be contacted with the first pad unit of the second area of the printed circuit board exposed through the window.

The first pad unit and the second pad unit are attached for each other by conductive adhesive.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exploded perspective view of a display apparatus according to an embodiment of the present disclosure.

FIG. 2 is a rear view in which some configurations are omitted from FIG. 1 according to an embodiment of the present disclosure.

FIG. 3 is a plan view of a plate of the display apparatus according to an embodiment of the present disclosure.

FIG. 4 is a cross-sectional view taken along line A-A' of FIG. 2 according to an embodiment of the present disclosure.

FIG. 5 is the view illustrating that a driving device is mounted on the flexible circuit film in the display apparatus according to the embodiment of the present disclosure.

FIG. 6 is a partial cross-sectional view illustrating that a plate is bonded to a printed circuit board in the display apparatus according to the embodiment of the present disclosure.

FIG. 7 is the view illustrating in more detail the flexible circuit film in the display apparatus according to the embodiment of the present disclosure.

FIG. 8 is a schematic block diagram of the display panel according to the present disclosure.

FIG. 9 is the cross-sectional view illustrating a structure of the display panel according to the present disclosure in detail.

FIG. 10 is the view illustrating a portion of the display apparatus according to another embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

Any implementation described herein as an “example” is not necessarily to be construed as preferred or advantageous over other implementations.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical idea of the present disclosure.

In describing the components of the disclosure, terms such as first, second, A, B, (a), (b), etc. may be used. These terms are only for distinguishing the elements from other elements, and the essence, order, or number of the elements are not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Also, when an element or layer is “connected,” “coupled,” or “adhered” to another element or layer denotes that the element or layer can not only be directly connected or adhered to another element or layer, but also be indirectly connected or adhered to another element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example, consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the present disclosure will be described in detail with reference to the accompanying drawings.

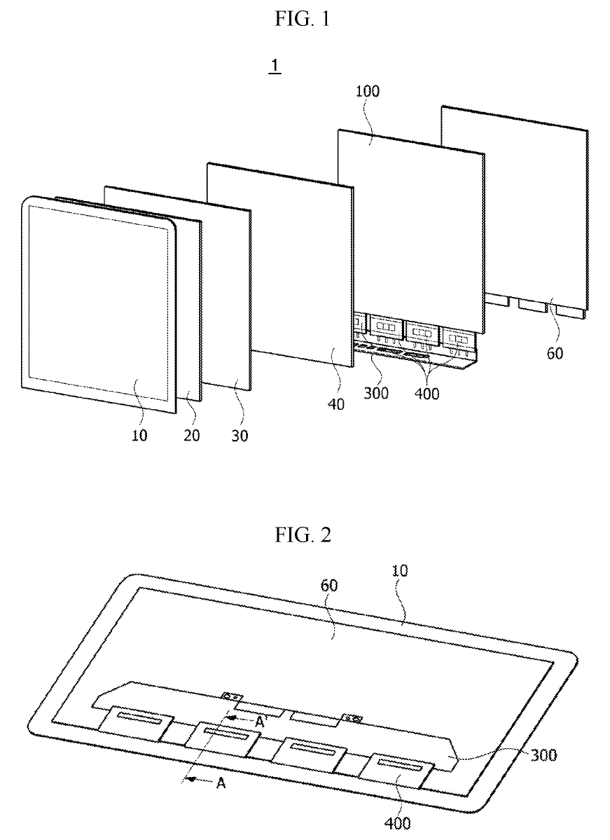

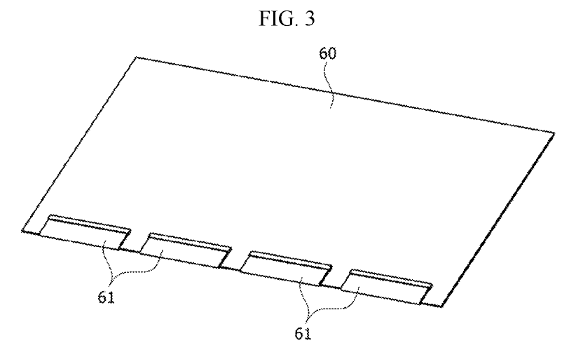

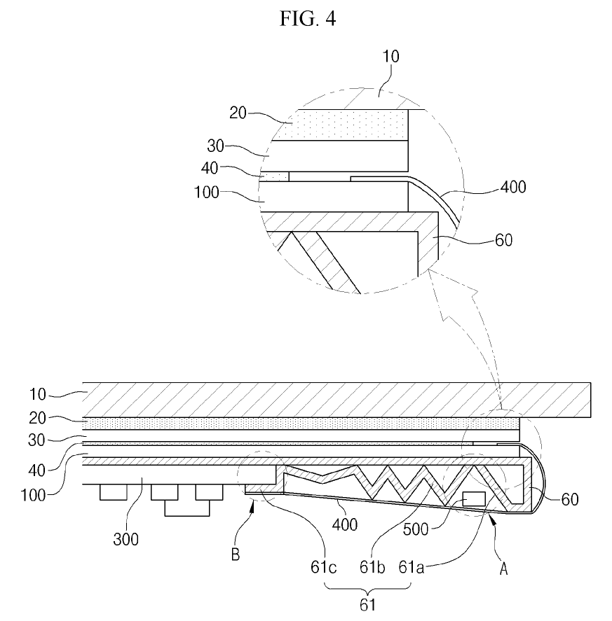

FIG. 1 is an exploded perspective view of the display apparatus according to an embodiment of the present disclosure, and FIG. 2 is a rear view in which some configurations are omitted from FIG. 1. FIG. 3 is a plan view of a plate of the display apparatus according to the embodiment of the present disclosure. FIG. 4 is a cross-sectional view taken along line A-A' of FIG. 2.

The display apparatus according to the present disclosure may be applied to various fields. For example, the display apparatus of the present disclosure may be mounted on a vehicle to provide the image necessary for driving to a driver and a passenger of the vehicle. However, the present disclosure is not limited thereto, and may be used in a portable device rather than the vehicle. Hereinafter, the display apparatus mounted on the vehicle is described as an example, but is not limited thereto.

As shown in FIGS. 1 to 4, the display apparatus 1 according to the present disclosure may include a display panel 100, a plate 60 disposed on a rear surface of the display panel 100, a printed circuit board 300 (PCB) electrically connected to the display panel 100, and a flexible circuit film (chip on film COF) 400.

An image may be displayed on the display panel 100. The displayed image may be, for example, navigation information necessary for driving, an image photographed by a camera mounted on a vehicle, or other various contents necessary for the driver or the passenger, but is not limited thereto.

The printed circuit board 300 may be electrically connected to the display panel 100. A camera, a communicating device with an external device such as main control module of the vehicle, the device for driving the display panel 100, and the like may be mounted on the printed circuit board 300. In addition, an internal circuit may be provided, and various other active elements and passive elements may be included.

One side of the flexible circuit film 400 may be electrically connected to the display panel 100 and the other side thereof may be electrically connected to the printed circuit board 300. A part of the flexible circuit film 400 is bent toward the rear surface of the display panel 100. FIG. 1 illustrates an example of a state in which the flexible circuit film 400 is unfolded.

The flexible circuit film 400 is formed of a thin film that may be bent to electrically connect the display panel 100 and the printed circuit board 300. Various active elements and passive elements may be provided in the flexible circuit film 400, and the driving circuit for driving the display panel 100 may be provided.

The driving circuit for driving the display panel 100 may be distributed and disposed on the printed circuit board 300 and the flexible circuit film 400, respectively. Referring to FIGS. 3 and 4, the flexible circuit film 400 may include a driving device 500 that forms at least a portion of the driving circuit of the display panel 100. The driving device 500 may be formed of an integrated circuit. A plurality of flexible circuit films 400 may be provided. For example, referring to FIG. 2, a plurality of flexible circuit films 400 may be disposed to be spaced apart from each other.

The cover member 10, the first adhesive member 20, the functional film 30, and the second adhesive member 40 are disposed above the display panel 100. The plate 60 is disposed below the display panel 100.

The cover member 10 is disposed in front of the display panel 100 to protect the display panel 100. The cover member 10 is made of a transparent material so that light output from the display panel 100 passes through the cover member 10.

The functional film 30 may include a viewing angle adjustment structure for adjusting a viewing angle of the image displayed on the display panel 100. The viewing angle adjustment structure may be provided within the functional film 30 in a trapezoidal pattern in which the angle is adjusted according to a desired viewing angle range when viewed in cross section. The trapezoidal pattern may be made of a light-shielding material, but is not limited thereto. For example, the functional film 30 may include a polarizer that controls display characteristics (e.g., reflection of external light, color accuracy, luminance, etc.).

Further, the functional film 30 may be patterned at the uppermost side of the display panel 100 or the inner surface of the cover member 10 instead of separate component. The first adhesive member 20 is disposed between the cover member 10 and the functional film 30 to attach the cover member 10 and the functional film 30. The second adhesive member 40 is disposed between the functional film 30 and the display panel 100 to attach the functional film 30 and the display panel 100.

The first adhesive member 20 and the second adhesive member 40 may be made of the material having good adhesive and transparent, for example, optically clear adhesive (OCA), press sensitive adhesive (PSA), or optically clear resin (OCR), but are not limited thereto.

Meanwhile, the functional film 30 may be omitted. For example, when the display apparatus 1 of the present disclosure is applied to a dashboard or the like of the vehicle, since the viewing direction of the image needs to be limited to a specific direction, the functional film 30 must be provided. However, when the display apparatus 1 is applied to the electronic device used by a large number of users such as a TV, there is no need to limit the viewing direction, and thus the functional film 30 and the adhesive member for attaching the same are not necessary.

The plate 60 is disposed behind the display panel 100. The plate 60 serves as a heat sink for cooling the display panel 100 by dissipating heat generated from the display panel 100 to the outside. The plate 60 may be made of the material that is easy to manufacture by processing sheet metal, has high heat transfer (heat conductivity), and has excellent resistance. For example, the plate 60 may be made of aluminum (Al), copper (Cu), graphite, or the like, but is not limited thereto.

The flexible circuit film 400 made of the thin film is bent from the front surface to the rear surface of the display panel 100 so that the bent area of the flexible circuit film 400 is disposed on the rear surface of the display panel 100. In this case, one side of the flexible circuit film 400 is connected to the display panel 100, and the other side of the flexible circuit film 400 is connected to the printed circuit board 300. Further, one side of the flexible circuit film 400 is electrically connected to the display panel 100, and the other side of the flexible circuit film 400 is electrically connected to the printed circuit board 300

As shown in FIG. 3, the plate 60 may include at least one extension portion 61 protruding from the side surface of the plate 60. For example, in the non-display area of the display apparatus, the extension portion 61 of the plate 60 may be overlapped with the flexible circuit film 400 on the rear surface of the flexible circuit film 400. For example, the flexible circuit film 400 may be bent toward the rear surface of the display panel 100 and the extension portion 61 of the plate 60 may be bent from one side of the plate 60 toward the rear surface of the display panel 100. That is, the flexible circuit film 400 and the extension portion 61 of the plate 60 may be bent in the same direction. The extension portion 61 of the plate 60 supports (guides) the flexible circuit film 400 to prevent or reduce cracks in the connection portion 450 of the flexible circuit film 400, thereby preventing or reducing separation of the display panel 100 from one side of the flexible circuit film 400 due to the external impact or the like when the display apparatus module or the product is transported or moved.

The driving device 500 is disposed on the rear surface of the display panel 100. The driving device 500 may be, for example, the data driving device of an integrated circuit type. The driving device 500 may be disposed between the flexible circuit film 400 and the plate 60.

The extension portion 61 of the plate 60 includes a bending portion 61a, a multi-bending portion 61b, and a connection portion 61c.

The bending portion 61a of the extension portion 61 is bent from the front surface to the rear surface of the display panel 100. In this case, the bending portion 61a is contacted with the bending area of the flexible circuit film 400 that is bent from the front surface to the rear surface of the display panel 100 to guide the flexible circuit film 400.

The multi-bending portion 61b is formed between the bending portion 61a and the connection portion 61c. The multi-bending portion 61b is formed by bending the extension portion 61 of the plate 60 from the bending portion 61a to the connection portion 61c multiple times. The multi-bending portion 61b is bent in a polygonal shape and partially contacts the plate 60. For example, the multi-bending portion 61b is bent in a triangular or zigzag shape, so that some triangular vertices or zigzag-shaped first vertices 61b_1 is contacted with the rear surface of the plate 60 and the second vertex 61b_2 faces the rear surface of the display apparatus 1.

The second vertex 61b_2 of the multi bending portion 61b supports the flexible circuit film 400 that is bent toward the rear surface of the display apparatus 1. Since the plate 60 is made of the metal such as aluminum, the multi bending portion 61b supports the flexible circuit film 400 when the flexible circuit film 400 is bent. Therefore, the movement of the flexible circuit film 400 due to the external force is prevented or reduced, thereby preventing or reducing the crack of the connection portion 450 of the flexible circuit film 400.

As shown in FIG. 5, the driving device 500 mounted on the flexible circuit film 400 may be disposed in a space formed by the multi-bending portion 61b and the flexible circuit film 400.

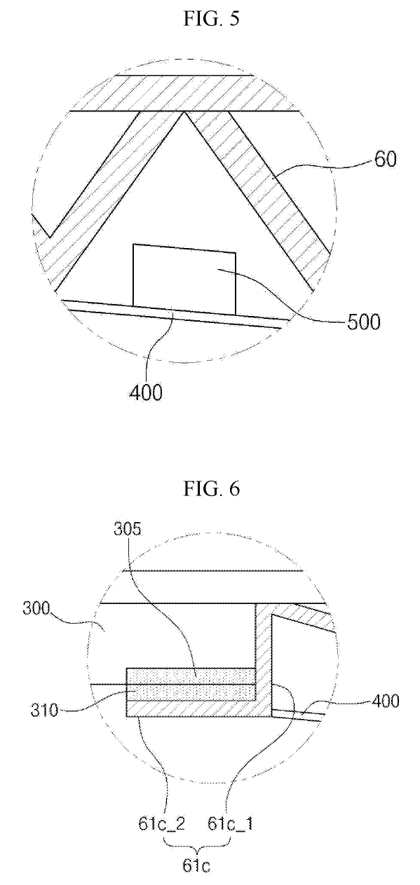

The printed circuit board 300 and the flexible circuit film 400 are electrically connected to each other at the connection portion 61c. As shown in FIG. 6, a conductive part 305 is formed on the upper surface of the printed circuit board 300 on which the connection portion 61c of the extension portion 61 of the plate 60 is located, that is, the upper surface of the end portion of the printed circuit board 300, and the conductive member 310 is disposed thereon. The conductive part 305 may be a copper foil formed on the printed circuit board 300, but is not limited thereto. For example, the conductive part 305 may be the copper foil from which a portion of an outer cover layer of the printed circuit board 300 is removed and exposed to the outside.

Further, the conductive member 310 may be a double-sided conductive tape, but is not limited thereto. The double-sided conductive tape may include a base and conductive adhesive layers disposed on both surfaces of the base. The base may be formed of a base film or a thin metal, and the conductive adhesive layer may be formed of the adhesive in which conductive powder is dispersed.

The connection portion 61c includes a first connection area 61c_1 disposed at the side surface of the printed circuit board 300 and a second connection area 61c_2 disposed on the upper surface of the printed circuit board 300. The first connection area 61c_1 and the second connection area 61c_2 may be integrally formed. Further, the first connection area 61c_1 and the second connection area 61c_2 may be bent vertically from the side surface to the upper surface of the printed circuit board 300.

The conductive member 310 is disposed between the upper surface of the printed circuit board 300 and the rear surface of the second connection area 61c_2 to electrically connect the printed circuit board 300 to the second connection area 61c_2. Since the extension portion 61 of the plate 60 is integrally formed with the plate 60, the printed circuit board 300 and the plate 60 are electrically connected by the conductive member 310.

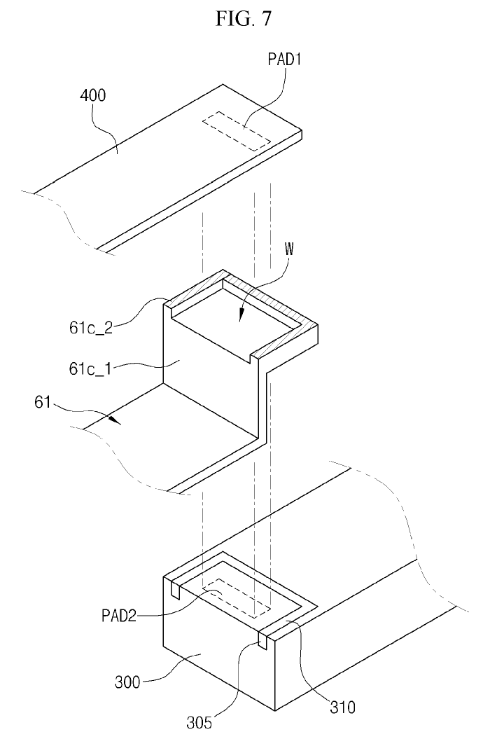

FIG. 7 is the view illustrating in more detail the connection between the extension portion 61 of the plate 60 and the printed circuit board 300. In this case, for convenience of description, the flexible circuit film 400, the plate 60, and the printed circuit board 300 are separated.

As shown in FIG. 7, the first connection area 61c_1 of the plate 60 is formed in the thickness direction of the printed circuit board 300, and the second connection area 61c_2 is formed perpendicular to the first connection area 61c_1. In the second connection area 61c_2, a window W from which the partial region is removed is formed. As the window W is formed, the second connection area 61c_2 is formed in a shape in which a metal band having conductivity surrounds the window W on three surfaces.

The conductive member 310 is formed on the upper surface of the printed circuit board 300. The conductive member 310 is formed in the shape corresponding to the second connection area 61c_2 of the plate 60, so that the conductive member 310 is disposed in a thin band shape at the upper end portion of the printed circuit board 300.

When the connection portion 61c of the plate 60 is attached to the upper surface of the printed circuit board 300, the second connection area 61c_2 and the conductive member 310 are attached to each other in an aligned state to form a ground portion. That is, the static electricity generated from the display panel 100 is introduced through the extension portion 61 of the plate 60 and then is discharged from the ground region to the conductive member 310 of the printed circuit board 300.

As described above, in the present disclosure, the static electricity generated in the display panel 100 is quickly discharged through the plate 60 made of the metal plate such as aluminum having very good conductivity, so that the image quality defects by the static electricity can be prevented or reduced.

A first pad unit PAD1 is formed on the bottom surface of the flexible circuit film 400, and a second pad unit PAD2 is formed on the top surface of the printed circuit board 300. The first pad unit PAD1 and the second pad unit PAD2 corresponds to the window W of the plate 60.

When the extension portion 61 of the plate 60 and the flexible circuit film 400 are attached to the printed circuit board 300, the extension portion 61 of the plate 60 is attached to the printed circuit board 300 first. When the extension portion 61 of the plate 60 is attached to the printed circuit board 300, a part of the upper surface of the printed circuit board 300 is exposed to the outside through the window W of the extension portion 61 of the plate 60. In this case, a second pad unit PAD_2 is disposed on the exposed upper surface of the printed circuit board 300 so that the second pad unit PAD_2 is exposed to the outside through the window W.

Subsequently, the first pad unit PAD1 of the lower surface of the flexible circuit film 400 is aligned with the second pad unit PAD_2 of the upper surface of the printed circuit board 300, which is exposed to the outside through the window W of the extension portion 61 of the plate 60, and then the flexible circuit film 400 is attached to the printed circuit board 300.

Since the first pad unit PAD1 and the second pad unit PAD_2 are bonded by a conductive adhesive, the flexible circuit film 400 is attached to the printed circuit board 300 and the flexible circuit film 400 is electrically connected to the printed circuit board 300.

As described above, in the present disclosure, since the flexible circuit film 400 is supported by the plate 60, the crack of the connection portion 450 of the flexible circuit film 400 connected to the display panel 100 due to the external impact or the like may be prevented or reduced. As a result, separation of the flexible circuit film 400 from the display panel 100 may be prevented or reduced.

Further, in the present disclosure, since the plate 60 is electrically connected to the display panel 100 and the printed circuit board 300, the static electricity generated in the display panel 100 can be easily discharged to the outside through the printed circuit board 300, thereby preventing or reducing poor image quality of the display apparatus 1 due to static electricity.

Meanwhile, the present disclosure may be applied to various display apparatus 1. For example, the present disclosure may be applied to the organic light emitting display apparatus.

Hereinafter, the organic light emitting display apparatus applied to the present disclosure will be described with reference to the accompanying drawings.

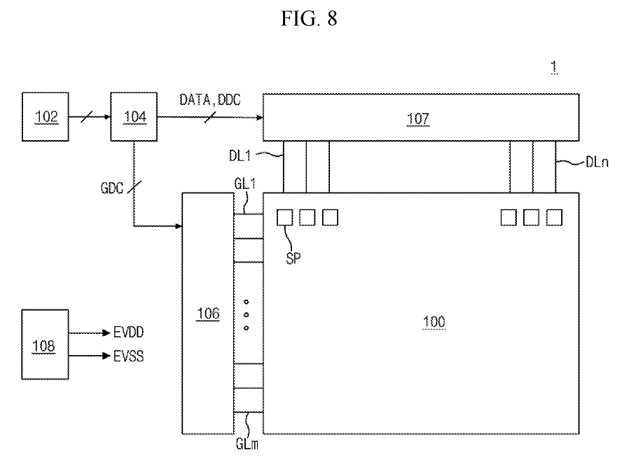

FIG. 8 is a schematic block diagram of the display apparatus according to the present disclosure.

As shown in FIG. 8, the display apparatus 1 includes an image processing unit 102, a timing controlling unit 104, a gate driving unit 106, a data driving unit 107, a power supplying unit 108, and the display panel 100.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 100 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driving unit 106 includes various gate driving circuits, and the gate driving circuit can be formed directly on the substrate of the display panel 109. In this case, the gate driving unit 106 can be a GIP (Gate-In-Panel).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 100 displays the image based on the data voltage from the data driving unit 107, the scan signal from the gate driving unit 106, and the power from the power supplying unit 108.

The display panel 100 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

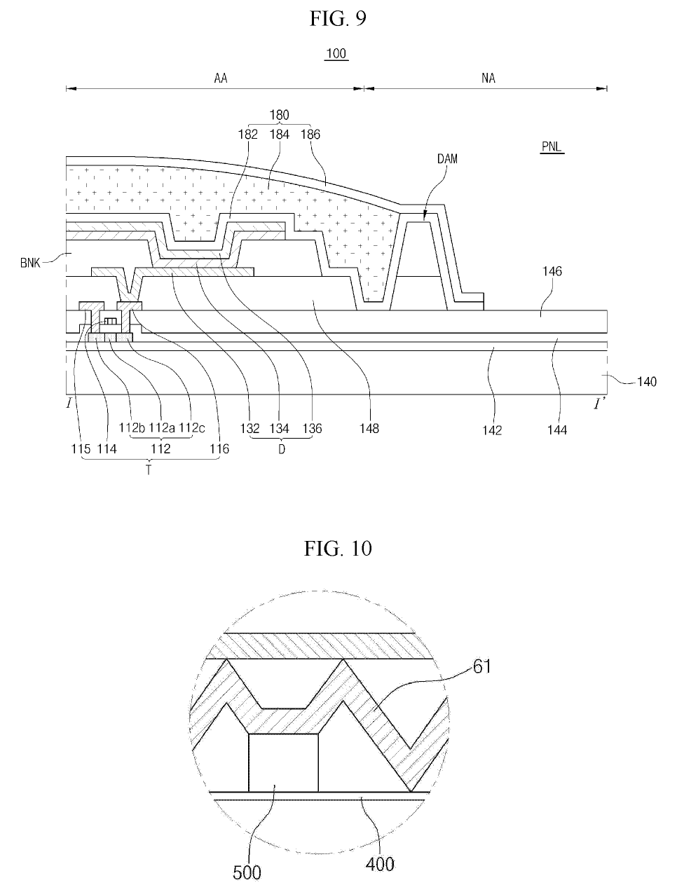

FIG. 9 is a cross-sectional view illustrating the structure of the display panel 100 according to the present disclosure.

As shown in FIG. 9, the substrate 140 includes the display area AA and the non-display area NA. The substrate 140 may be made of a hard material such as a glass or a flexible plastic material.

If the substrate 140 is made of the plastic material, the plastic material may include a polyimide, a polymethylmethacrylate, a polyethylene tereththalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

A thin film transistor is formed on the buffer layer in each sub-pixel SP1 and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be formed in the entire area of the substrate 140 or formed only in a part area of the substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be formed in the display area AA and the non-display area NA or may be formed only in the display area AA. The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes or reduces a backchannel phenomenon caused by charges trapped in the substrate 140 to prevent or reduce afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor is disposed. The planarization layer 148 may be formed of the organic material such as photoacrylic. But it is not limited thereto. The planarization layer 148 may include a plurality of layers including the inorganic layer and the organic layer.

A light emitting device D is disposed in each sub-pixel SP1 and SP2 on the planarization layer 148. The light emitting device D includes a first electrode 132, a light emitting layer 134, and a second electrode 136.

The first electrode 132 is disposed on the planarization layer 148 and electrically connected to the drain electrode 116 of the thin film transistor through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 1 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BNK is formed at the boundary between the sub-pixels on the planarization layer 148. The bank layer 152 may be a barrier wall to define sub-pixels. The bank layer BNK divides each sub-pixel to prevent or reduce light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The light emitting layer 134 is formed on the upper surface of the first electrode 132, the inclined surface of the bank layer BNK, and a portion of the upper surface of the bank layer BNK of the display area AA, and may extend to the non-display area NA.

The light emitting layer 134 may be formed in R, G, and B pixels and include an R-light emitting layer for emitting red light, a G-light emitting layer for emitting green light, and a B-light emitting layer for emitting blue light. For example, the light emitting layer 134 may be the organic light emitting layer, an inorganic light emitting layer, a nano-sized material layer, a quantum dot layer, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the single layer or the multi layers made of the metal or the alloy thereof. Further, the second electrode 136 may be made of the transparent metal oxide material such as ITO or IZO, but is not limited thereto.

When the display apparatus 1 is the top emission type, the second electrode 136 may be made of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 1 is the bottom emission type, the second electrode 136 may be the reflective electrode made of the opaque conductive material. For example, the second electrode 188 may be made of at least one or more of silver (Ag), aluminum (Al), gold (Au), molybdenum (Mo), tungsten (W), chromium (Cr), or alloys thereof.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge

generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 180 is formed in the display area AA and the non-display area NA to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D oxidizes the metal electrode. The encapsulation layer 180 blocks impurities such as oxygen and moisture from the outside to prevent or reduce defects of the light emitting device D and various electrodes.

The encapsulation layer 180 may be formed of a first encapsulation layers 182a, 182b, and 182c, a second encapsulation layer 184, and a third encapsulation layer 186, but is not limited thereto. The encapsulation layer 180 may be formed of two layers or four or more layers.

The first encapsulation layer 182 and the third encapsulation layer 186 may be made of the inorganic material such as SiOx or SiNx, but are not limited thereto. The second encapsulation layer 184 may be made of the organic insulating material such as acrylic resin, epoxy resin, polyimide, polyethylene, or silicon oxycarbon (SiOC), but is not limited thereto.

Further, the third encapsulation layer 186 may be made of thin metal (Face Seal Metal), but is not limited thereto.

Although not shown in figure, a touch member may be disposed on the encapsulation layer 180. The touch member can detect external touch information using the user's finger or a touch pen.

A dam DAM is formed outside the non-display area NA. Since the organic material forming the second encapsulation layer 184 has fluidity, the organic material may flow out to the outside of the substrate 140 by the fluidity when the second encapsulation layer 184 is formed. Since the dam DAM is formed to surround the display area NA, the organic materials flowing out of the substrate 140 may be contained by the dam DAM when the second encapsulation layer 184 is formed. Therefore, the organic material does not flow out of the substrate 140. In the figure, although only one dam DAM is shown, the multiple dams DAM may be disposed.

The dam DAM may be formed of the multiple layers. For example, the dam DAM may be formed of two layers made of the same material as the planarization layer 148 and the bank layer BNK. However, the dam DAM of the present disclosure is not limited thereto and may be formed of the single layer or three or more layers.

FIG. 10 is the view illustrating the display apparatus according to another embodiment of the present disclosure. The display apparatus of this embodiment has the same structure as the display apparatus shown in FIG. 4 except for the structure of the plate, and thus only the structure of the plate is shown.

As shown in FIG. 10, in the display apparatus of the present embodiment, the driving device 500 is mounted on one surface of the flexible circuit film 400, and a part of the extension portion 61 of the plate 60 is contacted with the upper surface of the driving device 500. Therefore, the heat generated by the driving device 500 may be discharged to the printed circuit board 300 through the plate 60.

The above description and the accompanying drawings are merely illustrative of the technical idea of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical idea of the present disclosure, but to explain, and the scope of the technical idea of the present disclosure is not limited by these embodiments.

What is claimed is:

1. A display apparatus, comprising:
a plate;
a display panel over the plate;
a printed circuit board below the plate; and
a flexible circuit film for connecting electrically the display panel and the printed circuit board,
wherein the plate includes an extension portion bent toward a rear surface of the display panel, and
wherein the extension portion is bent multiple times in a polygonal shape so that a first side of the extension portion is contacted with the rear surface of the plate and a second side of the extension portion is contacted with the flexible circuit film to support the flexible circuit film.

2. The display apparatus of claim 1, further comprising a driving device mounted on the flexible circuit film and disposed between the flexible circuit film and the extension portion of the plate.

3. The display apparatus of claim 2, wherein the driving device is contacted with the extension portion of the plate.

4. The display apparatus of claim 1, wherein the printed circuit board including:
a first part formed on an upper surface of the printed circuit board to be connected electrically to the plate; and
a second part formed on the upper surface of the printed circuit board to be connected electrically to the flexible circuit film.

5. The display apparatus of claim 4, wherein the first part is a copper foil.

6. The display apparatus of claim 4, wherein a double-sided conductive tape is disposed between the first part and the plate.

7. The display apparatus of claim 4, wherein the first part surrounds the second part.

8. The display apparatus of claim 7, wherein a first pad unit is formed in the second part.

9. The display apparatus of claim 8, wherein a window is formed in the plate corresponding to the second part of the printed circuit board, so that the second part is exposed through the window.

10. The display apparatus of claim 9, wherein a second pad unit is formed at an end of the flexible circuit film to be contacted with the first pad unit of second area of the printed circuit board exposed through the window.

11. The display apparatus of claim 10, wherein the first pad unit and the second pad unit are attached for each other by conductive adhesive.

12. The display apparatus of claim 1, wherein the plate is made of a metal.

13. A display apparatus, comprising:
a plate;
a display panel over the plate;
a printed circuit board below the plate;
a flexible circuit film for connecting electrically the display panel and the printed circuit board; and
a driving device mounted on the flexible circuit film, and the driving device is disposed between the flexible circuit film and an extension portion of the plate,
wherein the extension portion is bent toward a rear surface of the display panel,
wherein the extension portion is contacted with the driving device to discharge heat generated from the driving device, and
wherein the extension portion is bent multiple times in a polygonal shape so that a first side of the extension portion is contacted with the rear surface of the plate and a second side of the extension portion is contacted with the flexible circuit film to support the flexible circuit film.
